(19) United States
(12) Patent Application Publication
(10) Pub. No.: US 2025/0311295 A1
(43) Pub. Date: Oct. 2, 2025

(54) SUSPENSION REGION CONFIGURATION FOR SEMICONDUCTOR DEVICES

(71) Applicant: International Business Machines Corporation, Armonk, NY (US)

(72) Inventors: Chanro Park, Clifton Park, NY (US); Ruilong Xie, Niskayuna, NY (US); Juntao Li, Cohoes, NY (US); Min Gyu Sung, Latham, NY (US); Julien Frougier, Albany, NY (US)

(21) Appl. No.: 18/616,911

(22) Filed: Mar. 26, 2024

(51) Int. Cl. H01L 29/417; H01L 23/528; H01L 29/06; H01L 29/40; H01L 29/423; H01L 29/66; H01L 29/775

(52) U.S. Cl. CPC H10D 30/6729; H01L 23/5286; H10D 30/014; H10D 30/43; H10D 30/6735; H10D 62/121; H10D 64/01; H10D 64/017; H10D 64/018

(57) ABSTRACT

A semiconductor device includes a first stacked transistor structure and a second stacked transistor structure disposed above an interlayer dielectric layer, each comprising a plurality of channel layers alternately stacked with a plurality of gate regions, and a first source/drain region that contacts the plurality of channel layers of the first stacked transistor structure and the second stacked transistor structure. At least a portion of the first source/drain region that is above the interlayer dielectric layer and below a first channel layer of the plurality of channel layers is disposed between curved-shaped inner spacer structures of the first stacked transistor structure and the second stacked transistor structure. A first source/drain contact is connected to the first source/drain region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor device includes a first stacked transistor structure and a second stacked transistor structure disposed above an interlayer dielectric layer, each including a plurality of channel layers alternately stacked with a plurality of gate regions, and a first source/drain region that contacts the plurality of channel layers of the first stacked transistor structure and the second stacked transistor structure. At least a portion of the first source/drain region that is above the interlayer dielectric layer and below a first channel layer of the plurality of channel layers is disposed between curved-shaped inner spacer structures of the first stacked transistor structure and the second stacked transistor structure. A first source/drain contact is connected to the first source/drain region.

In another illustrative embodiment, a semiconductor device includes a first source/drain region that contacts channel layers of a first stacked transistor structure and a second stacked transistor structure, a second source/drain region that contacts channel layers of the second stacked transistor structure and a third stacked transistor structure, and a backside source/drain contact connected to the second source/drain region. A bottom portion of the first source/drain region is disposed between a first curved-shaped inner spacer structure of the first stacked transistor structure and a second curved-shaped inner spacer structure of the second stacked transistor structure. The backside source/drain contact is disposed between a third curved-shaped inner spacer structure of the second stacked transistor structure and a fourth curved-shaped inner spacer structure of the third stacked transistor structure.

In another exemplary embodiment, a method includes forming a set of channel layers alternately stacked with a set of sacrificial layers on a semiconductor layer, where a first channel layer in the set of channel layers is thinner than the other channel layers in the set of channel layers, and forming indentations in the sacrificial layers in the set of sacrificial layers, where the indentations formed for the sacrificial layers adjacent to the first channel layer are deeper than the other sacrificial layers in the set of sacrificial layers. The method also includes forming inner spacers between each of the channel layers in the set of channel layers and forming a source/drain region and curved-shaped inner spacer structures, where the source/drain region is disposed between the curved-shaped inner spacer structures. At least a portion of the source/drain region is formed below the first channel layer in the set of channel layers, where forming the curved-shaped inner spacer structures includes removing the set of sacrificial layers and trimming at least the first channel layer.

Other embodiments will be described in the following detailed description of embodiments, which is to be read in conjunction with the accompanying figures.

### BRIEF DESCRIPTION OF THE DRAWINGS

FIG. 1 depicts a top view of a semiconductor structure with lines X and Y on which the cross-sectional views of FIGS. 2A-19B are based, according to an illustrative embodiment.

FIG. 2A depicts a first cross-sectional view corresponding to line X in FIG. 1 illustrating the semiconductor structure of FIG. 1 during an intermediate step of a method of fabricating a nanosheet transistor structure, according to an illustrative embodiment.

FIG. 2B depicts a second cross-sectional view corresponding to line Y in FIG. 1 illustrating the semiconductor structure of FIG. 1 during the intermediate step of the method of fabricating the nanosheet transistor structure, according to an illustrative embodiment.

FIG. 3A depicts a first cross-sectional view corresponding to the line X in FIG. 1 following nanosheet layer patterning and isolation region formation, according to an illustrative embodiment.

FIG. 3B depicts a second cross-sectional view corresponding to the line Y in FIG. 1 following the nanosheet layer patterning and the isolation region formation, according to an illustrative embodiment.

FIG. 4A depicts a first cross-sectional view corresponding to the line X in FIG. 1 following dummy gate, masking layer, and gate spacer formation, according to an illustrative embodiment.

FIG. 4B depicts a second cross-sectional view corresponding to the line Y in FIG. 1 following dummy gate, masking layer, and gate spacer formation, according to an illustrative embodiment.

FIG. 5A depicts a first cross-sectional view corresponding to the line X in FIG. 1 following nanosheet stack recessing, according to an illustrative embodiment.

FIG. 5B depicts a first cross-sectional view corresponding to the line Y in FIG. 1 following the nanosheet stack recessing, according to an illustrative embodiment.

FIG. 6A depicts a first cross-sectional view corresponding to the line X in FIG. 1 following sacrificial layer indentation, according to an illustrative embodiment.

FIG. 6B depicts a second cross-sectional view corresponding to the line Y in FIG. 1 following the sacrificial layer indentation, according to an illustrative embodiment.

FIG. 7A depicts a first cross-sectional view corresponding to the line X in FIG. 1 following conformal inner spacer liner deposition, according to an illustrative embodiment.

FIG. 7B depicts a second cross-sectional view corresponding to the line Y in FIG. 1 following the conformal inner spacer liner deposition, according to an illustrative embodiment.

FIG. 8A depicts a first cross-sectional view corresponding to the line X in FIG. 1 following an isotropic inner spacer liner etching process, according to an illustrative embodiment.

FIG. 8B depicts a second cross-sectional view corresponding to the line Y in FIG. 1 following the isotropic inner spacer liner etching process, according to an illustrative embodiment.

FIG. 9A depicts a first cross-sectional view corresponding to the line X in FIG. 1 following formation of a protective liner, according to an illustrative embodiment.

FIG. 9B depicts a second cross-sectional view corresponding to the line Y in FIG. 1 following the formation of the protective liner, according to an illustrative embodiment.

FIG. 10A depicts a first cross-sectional view corresponding to the line X in FIG. 1 following formation of placeholder cavity trenches, according to an illustrative embodiment.

FIG. 10B depicts a second cross-sectional view corresponding to the line Y in FIG. 1 following formation of the placeholder cavity trenches, according to an illustrative embodiment.

FIG. 11A depicts a first cross-sectional view corresponding to the line X in FIG. 1 following sacrificial placeholder formation, according to an illustrative embodiment.

FIG. 11B depicts a second cross-sectional view corresponding to the line Y in FIG. 1 following the sacrificial placeholder formation, according to an illustrative embodiment.

FIG. 12A depicts a first cross-sectional view corresponding to the line X in FIG. 1 following removal of portions of the protective liner and growth of epitaxial layers for source/drain regions, according to an illustrative embodiment.

FIG. 12B depicts a second cross-sectional view corresponding to the line Y in FIG. 1 following removal of portions of the protective liner and the growth of epitaxial layers for the source/drain regions, according to an illustrative embodiment.

FIG. 13A depicts a first cross-sectional view corresponding to the line X in FIG. 1 following formation of an interlayer dielectric (ILD) layer, a poly open chemical mechanical planarization (CMP) (POC) process, dummy gate removal, and sacrificial layer removal, according to an illustrative embodiment.

FIG. 13B depicts a second cross-sectional view corresponding to the line Y in FIG. 1 following formation of the ILD layer, the POC process, the dummy gate removal, and the sacrificial layer removal, according to an illustrative embodiment.

FIG. 14A depicts a first cross-sectional view corresponding to the line X in FIG. 1 following a nanosheet trimming process, according to an illustrative embodiment.

FIG. 14B depicts a second cross-sectional view corresponding to the line Y in FIG. 1 following the nanosheet trimming process, according to an illustrative embodiment.

FIG. 15A depicts a first cross-sectional view corresponding to the line X in FIG. 1 following replacement gate formation, middle-of-line (MOL) contact formation, back-end-of-line (BEOL) interconnect formation, and carrier wafer bonding, according to an illustrative embodiment.

FIG. 15B depicts a second cross-sectional view corresponding to the line Y in FIG. 1 following the replacement gate formation, the MOL contact formation, the BEOL interconnect formation, and the carrier wafer bonding, according to an illustrative embodiment.

FIG. 16A depicts a first cross-sectional view corresponding to the line X in FIG. 1 following wafer flipping and semiconductor substrate removal, according to an illustrative embodiment.

FIG. 16B depicts a second cross-sectional view corresponding to the line Y in FIG. 1 following the wafer flipping and the semiconductor substrate removal, according to an illustrative embodiment.

FIG. 17A depicts a first cross-sectional view corresponding to the line X in FIG. 1 following etch stop and remaining semiconductor layer removal, according to an illustrative embodiment.

FIG. 17B depicts a second cross-sectional view corresponding to the line Y in FIG. 1 following the etch stop and the remaining semiconductor layer removal, according to an illustrative embodiment.

FIG. 18A depicts a first cross-sectional view corresponding to the line X in FIG. 1 following backside ILD layer formation and backside ILD layer patterning for backside contacts, according to an illustrative embodiment.

FIG. 18B depicts a second cross-sectional view corresponding to the line Y in FIG. 1 following the backside ILD layer formation and the backside ILD layer patterning for the backside contacts, according to an illustrative embodiment.

FIG. 19A depicts a first cross-sectional view corresponding to the line X in FIG. 1 following sacrificial placeholder removal, backside contact formation, and backside interconnect formation, according to an illustrative embodiment.

FIG. 19B depicts a second cross-sectional view corresponding to the line Y in FIG. 1 following the sacrificial placeholder removal, the backside contact formation, and the backside interconnect formation, according to an illustrative embodiment.

### DETAILED DESCRIPTION

Illustrative embodiments are described herein in the context of illustrative methods for configuring suspension regions for semiconductor devices, along with illustrative apparatus, systems and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. In FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (for example, to 2.5 nm and beyond), next-generation stacked FET (SFET) devices may be used. Next-generation SFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation SFET structures provide improved track height scaling, leading to structural gains (for example, such as 30-40% structural gains for different types of devices, such as logic devices, static random-access memory (SRAM) devices, etc.). In next-generation SFET structures, n-type, and p-type nanowires or nanosheets are stacked on each other, eliminating n-to-p separation bottlenecks, and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation SFET devices.

Although embodiments described herein are discussed in connection with nanosheet stacks, the embodiments are not necessarily limited thereto, and may similarly apply to nanowire stacks.

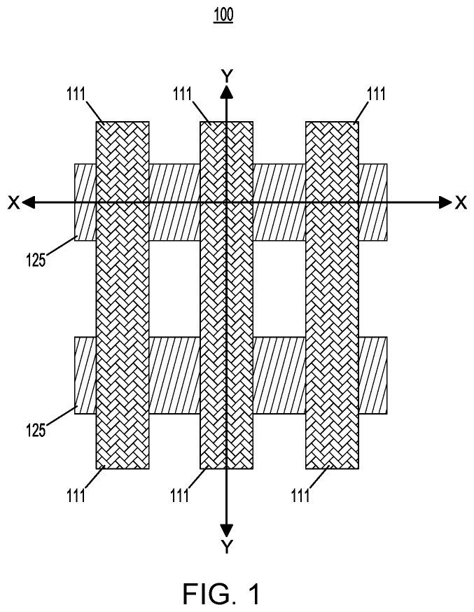

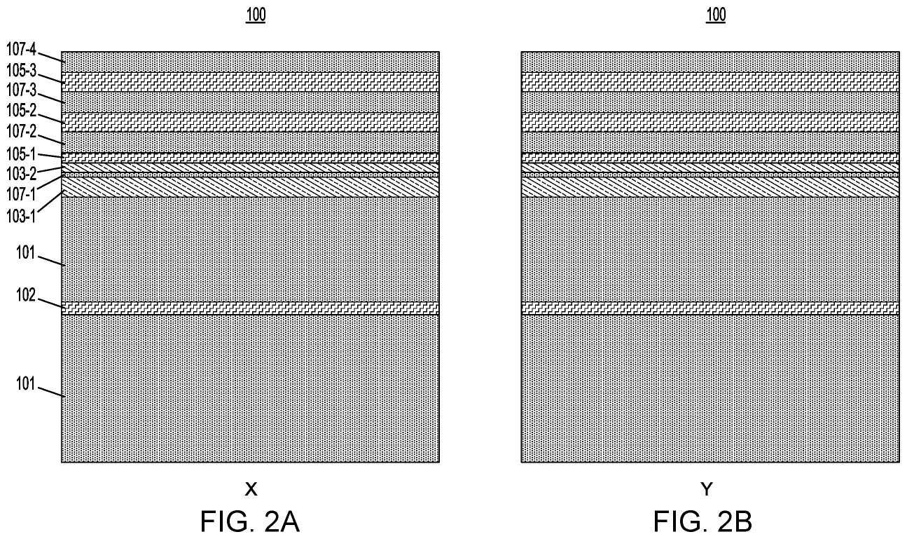

FIG. 1 depicts a top view of a semiconductor structure with lines X and Y on which the cross-sectional views of FIGS. 2A-19B are based, according to an illustrative embodiment. Referring to FIG. 1 and to the cross-sectional views in FIGS. 2A and 2B, which respectively correspond to the lines X and Y in FIG. 1, a semiconductor structure 100 includes a stacked structure of sacrificial layers 105-1, 105-2, and 105-3 (collectively “sacrificial layers 105”) and channel layers 107-1, 107-2, 107-3, 107-4 (collectively “channel layers 107”). In an illustrative embodiment, the sacrificial layers 105 comprise SiGe and the channel layers 107 comprise silicone.

The stacked structure also includes two additional sacrificial layers 103-1 and 103-2 (collectively “additional sacrificial layers 103”). The additional sacrificial layers 103 can be formed of SiGe with a different concentration of germanium than that of the sacrificial layers 105 so that at least portions of the additional sacrificial layers 103 can be selectively etched and removed with respect to the sacrificial layers 105. For example, the additional sacrificial layers 103 can have, but are not necessarily limited to, a germanium concentration of about 35% (for example, SiGe35), and the sacrificial layers 105 can have, but are not necessarily limited to, a germanium concentration of about 25% (for example, SiGe25).

In the example shown in FIGS. 2A and 2B, the channel layer 107-1 has a height that is smaller than the other channels layers 107 and is disposed between the additional sacrificial layers 103. As an example, each of the channel layers 107-2, 107-3, and 107-4 may have a height in the range of approximately 3 nm to about 15 nm and, and sacrificial layer 107-1 may have a height in the range of approximately 2 nm to about 5 nm.

While two additional sacrificial layers 103, three sacrificial layers 105, and four channel layers 107 (including the thinner channel layer 107-1) are shown, embodiments described herein are not necessarily limited to the shown number of additional sacrificial layers 103, sacrificial layers 105, and channel layers 107, and there may be more or less layers depending on design constraints. The additional sacrificial layers 103, sacrificial layers 105, and at least portions of the channel layer 107-1, as described further herein, are eventually removed, and replaced by gate structures.

The additional sacrificial layers 103, the sacrificial layers 105, and the channel layers 107 are epitaxially grown on a semiconductor layer 101 (also referred to herein as semiconductor substrate 101). The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe).

As used herein, “frontside or “first side” refers to a side on top of the semiconductor layer 101 and/or in front of, on top of or in an upward direction from the stacked gate and channel layers of the transistors in the orientation shown in the cross-sectional figures. As used herein, “backside” or “second side” refers to a side below the semiconductor layer 101 and/or behind, below or in a downward direction from the stacked gate and channel layers of the transistors in the orientation shown in the cross-sectional figures (for example, opposite the “frontside”).

An etch stop layer 102 is formed in the semiconductor layer 101. The etch stop layer 102 may comprise a buried oxide (BOX) layer or SiGe (e.g., SiGe25), or another suitable material such as a III-V semiconductor epitaxial layer. In some embodiments, the etch stop layer 102 can have a height in the range of 10 nm to 30 nm.

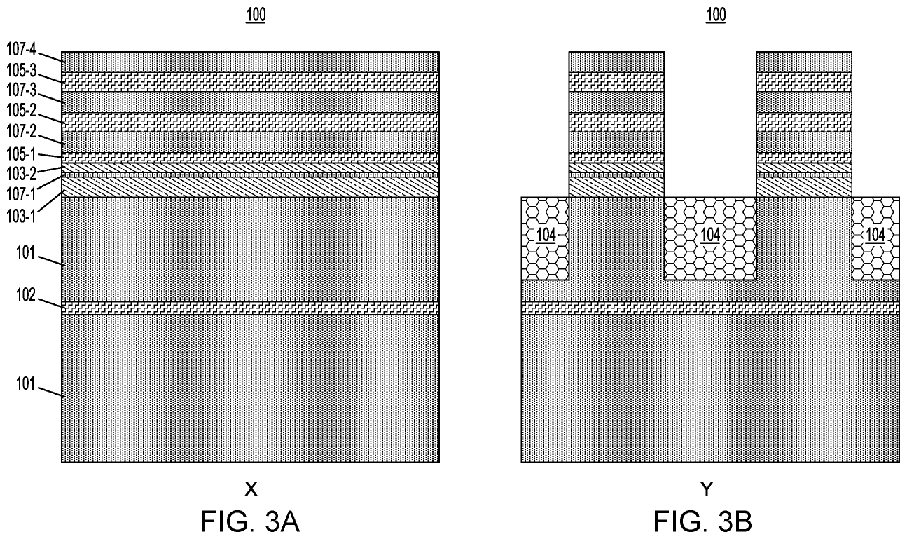

FIGS. 3A and 3B show cross-sectional views, which respectively correspond to the lines X and Y in FIG. 1, of the semiconductor structure 100 following nanosheet layer patterning and isolation region formation, according to an illustrative embodiment. Portions of the nanosheet stacks comprising the additional sacrificial layers 103, the sacrificial layers 105, and the channel layers 107 are removed, and portions of the semiconductor layer 101 are recessed. Isolation regions 104 (for example, shallow trench isolation (STI)) regions are formed between the remaining nanosheet stacks, and the remaining portions of the additional sacrificial layers 103, 106, and the semiconductor layer 101.

As can be seen in FIG. 3B, portions of the semiconductor layer 101 are removed, and portions of the semiconductor layer 101 are recessed to a lower height. Isolation regions 104 comprising dielectric material fill in the recessed portions of the semiconductor layer 101 and the vacant areas left by the removal of the portions of the semiconductor layer 101. The dielectric material may comprise, for example, silicon oxide (SiO₂), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

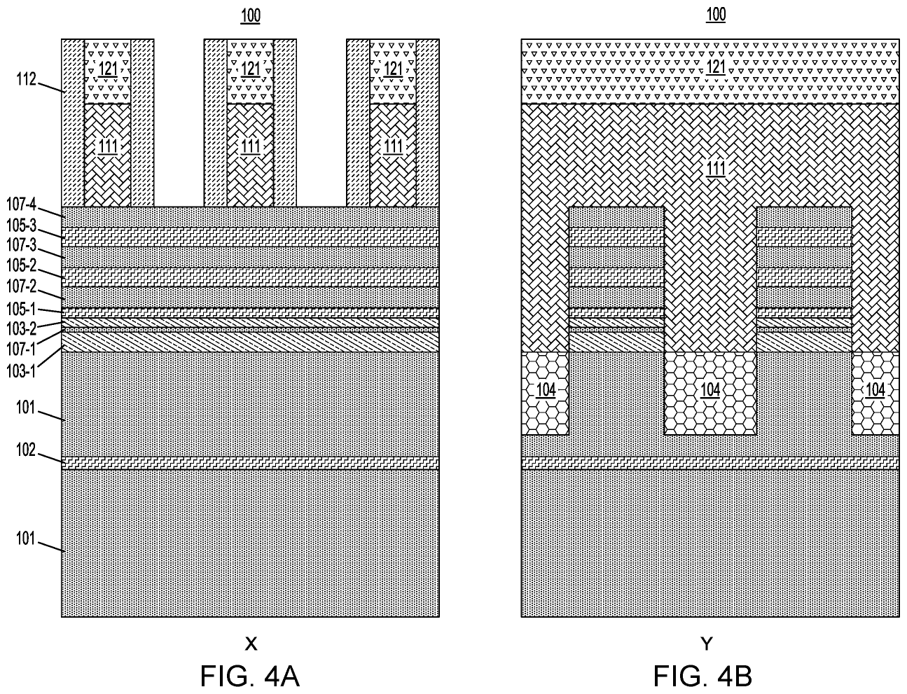

FIGS. 4A and 4B show cross-sectional views, which respectively correspond to the lines X and Y in FIG. 1, of the semiconductor structure 100 following formation of dummy gate portions 111, a hardmask (HM) layer 121, and gate spacers 112, according to an illustrative embodiment. In particular, the dummy gate portions 111 are formed on the uppermost channel layers 107-4 and around the stacked nanosheet configurations of the additional sacrificial layers 103, the sacrificial layers 105, and channel layers 107. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as, CMP, and lithography and etching steps to remove excess dummy gate material, and pattern the deposited layer. The HM layer 121 is formed on the dummy gate portions 111. The HM layer 121 may be formed using any conventional deposition technique such as by PVD, ALD, CVD, etc., followed by a planarization step such as a CMP process. The HM layer 121 can be formed of any suitable material such as, for example, oxide and nitride materials such as SiN, a multi-layer of SiN and SiO₂, or other suitable material.

As shown in FIG. 4A, the gate spacers 112 are formed on sides of the HM layer 121 and the dummy gate portions 111 by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. According to an embodiment, the HM layer 121 and the gate spacers 112 can be the same material or different materials. The gate spacers 112 can be formed by any suitable techniques such as deposition followed by directional etching. Deposition may include, but is not limited to, ALD or CVD. Directional etching may include but is not limited to, reactive ion etching (RIE).

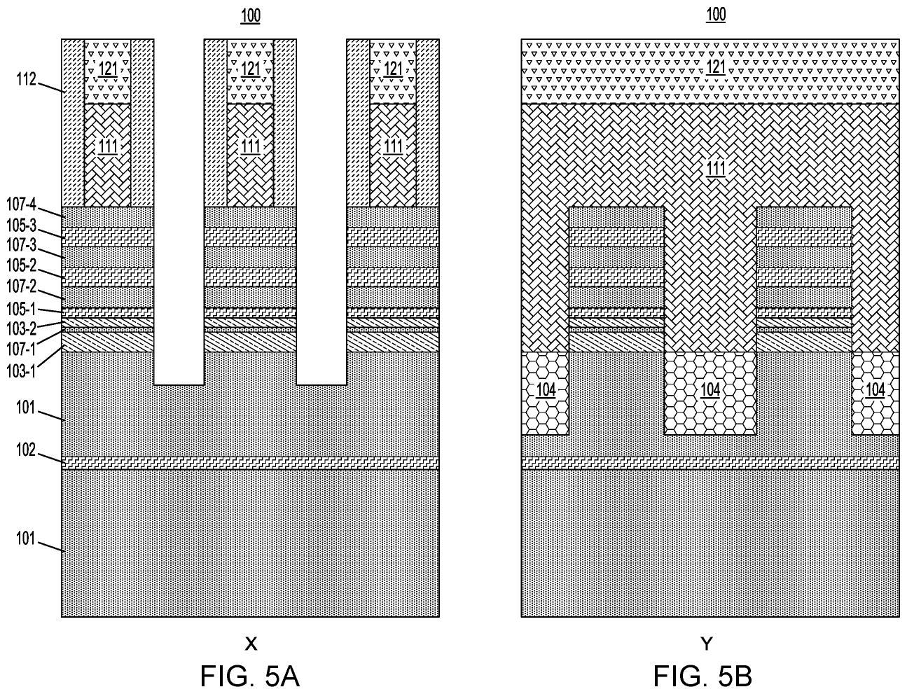

FIGS. 5A and 5B show cross-sectional views, which respectively correspond to the lines X and Y in FIG. 1, of the semiconductor structure 100 following nanosheet stack recessing, according to an illustrative embodiment. Exposed portions of the stacked additional sacrificial layers 103, the sacrificial layers 105, and the channel layers 107, which are not under the HM layer 121, the gate spacers 112, and the dummy gate portions 111, are removed using, for example, an etching process, such as RIE, where the HM layer 121, the gate spacers 112, and the dummy gate portions 111 are used as a mask. As can be seen in FIG. 5A, the portions of the stacked structures of the additional sacrificial layers 103, the sacrificial layers 105 and the channel layers 107 under the HM layer 121, the gate spacers 112, and the dummy gate portions 111 remain after the etching process, and portions of the additional sacrificial layers 103, sacrificial layers 105, and the channel layers 107 in areas that correspond to where source/drain regions will be formed are removed.

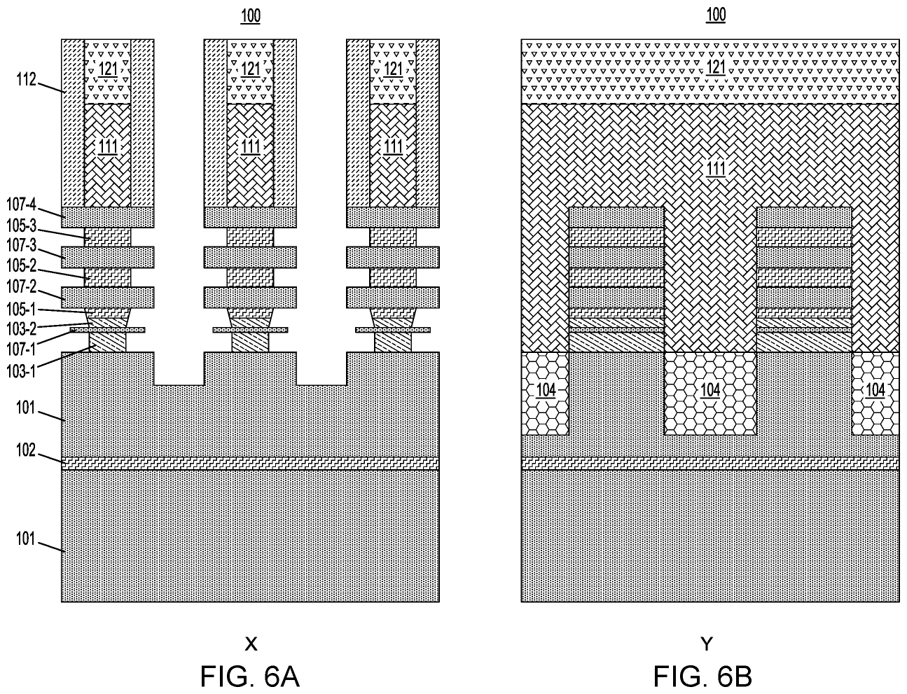

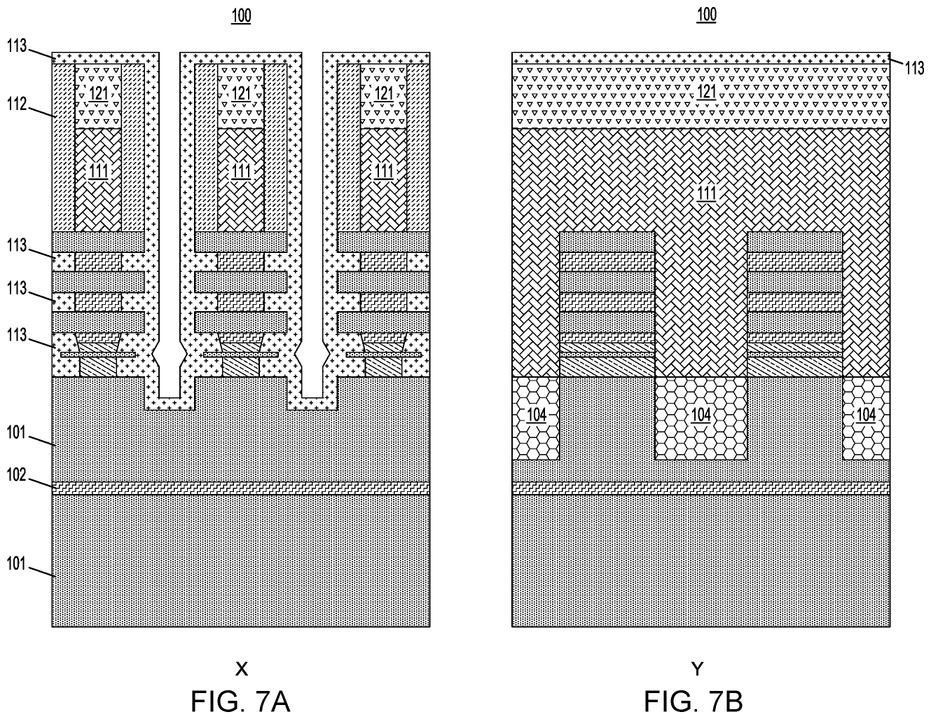

FIGS. 6A and 6B show cross-sectional views, which respectively correspond to the lines X and Y in FIG. 1, of the semiconductor structure 100 following indentation of the additional sacrificial layers 103 and the sacrificial layers 105, according to an illustrative embodiment. For example, an indention process can be performed to remove portions of the sacrificial layers 105 and portions of the additional sacrificial layers 103. The indentation process can form deeper indentations in the additional sacrificial layers 103 than the indentations formed in the sacrificial layers 105, as shown in FIG. 6A. Due to, for example, the germanium content in the additional sacrificial layers 103 being higher than that of the sacrificial layers 105, lateral etching can be performed selective to the channel layers 107, such that the side portions of the sacrificial layers 105 can be removed to create vacant areas to be filled in by inner spacers 114, as described in more detail in FIGS. 7A and 7B. The relatively higher germanium concentration in the additional sacrificial layers 103 can help prevent damage to the tips of the thinner channel layer 107-1, for example.

FIGS. 7A and 7B show cross-sectional views, which respectively correspond to the lines X and Y in FIG. 1, of the semiconductor structure 100 following conformal deposition of an inner spacer liner 113, according to an illustrative embodiment. In some embodiments, the inner spacer liner 113 comprises a dielectric material that is deposited over exposed vertical and horizontal surfaces of the semiconductor structure 100, as shown by FIGS. 7A and 7B.

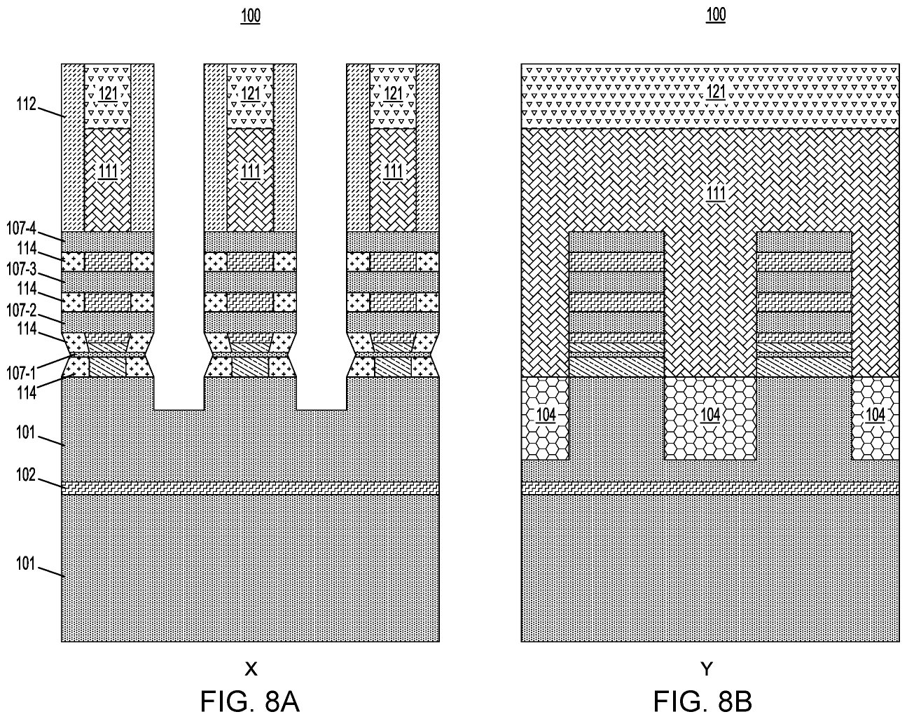

FIGS. 8A and 8B show cross-sectional views, which respectively correspond to the lines X and Y in FIG. 1, of the semiconductor structure 100 following an isotropic inner spacer liner etching process, according to an illustrative embodiment. A subsequent isotropic etch back is performed to remove excess of the dielectric material of the inner spacer liner 113 from vertical and horizontal surfaces of the semiconductor structure 100, thereby forming the inner spacers 114 between the channel layers 107. Suitable material for the inner spacers 114 includes, for example, SiN, SiBCN, silicon carbide oxide (SiCO), SiOCN or any other type of dielectric material (e.g., a dielectric material having a dielectric constant k of less than about 5).

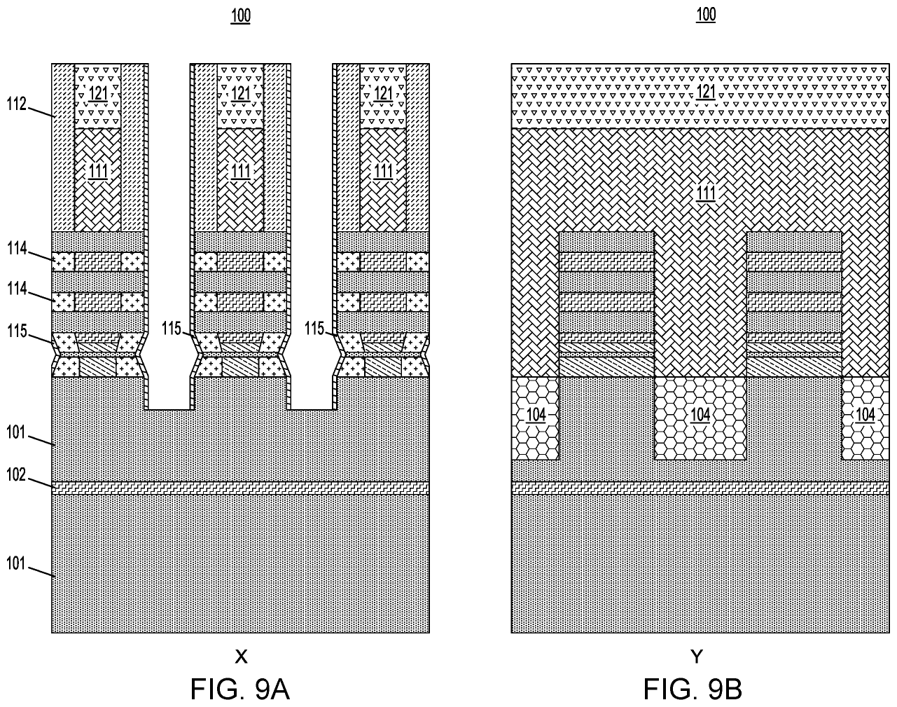

FIGS. 9A and 9B show cross-sectional views, which respectively correspond to the lines X and Y in FIG. 1, of the semiconductor structure 100 following formation of a protective liner 115, according to an illustrative embodiment. The protective liner 115 is formed on sidewalls of the channel layers 107, the gate spacers 112, and the inner spacers 114 above the exposed top surface of the semiconductor layer 101, as shown in FIG. 9A. In some embodiments, the protective liner 115 is formed using a conformal dielectric liner deposition process followed by an etching process, such as RIE. The protective liner 115 may be formed of SiN or another suitable material such as SiBCN, SiCOH, SiNCH, etc.

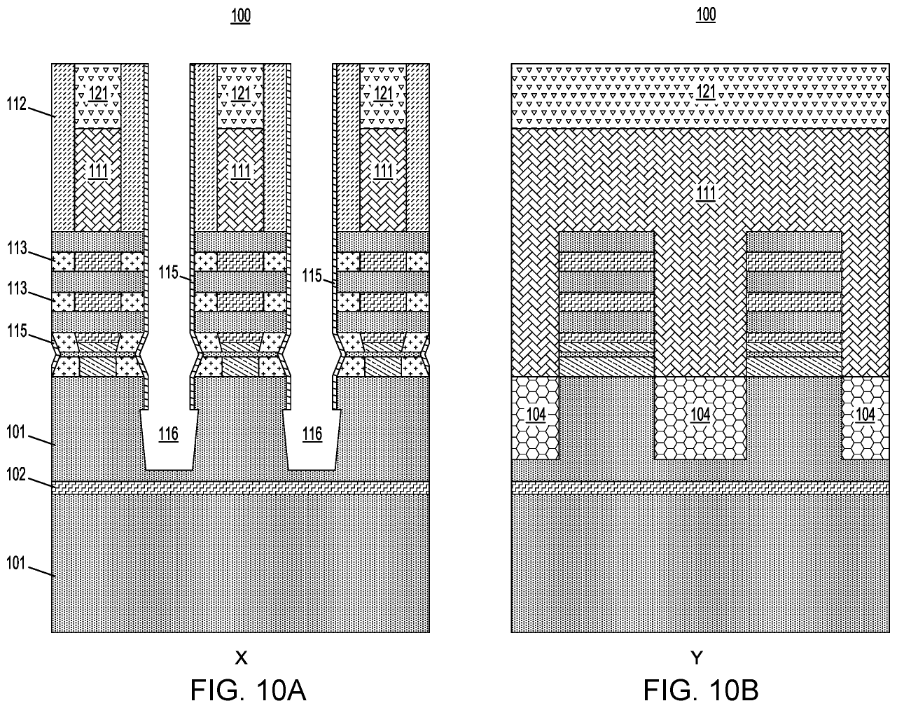

FIGS. 10A and 10B show cross-sectional views, which respectively correspond to the lines X and Y in FIG. 1, of the semiconductor structure 100 following formation of placeholder cavity trenches 116, according to an illustrative embodiment. More specifically, following formation of the protection liner 115, an etching process is performed to form the placeholder cavity trenches 116 into the semiconductor layer 101. In some embodiments, the placeholder cavity trenches 116 may be formed by performing a deep etch into the semiconductor layer 101 followed by lateral etch to widen the placeholder cavity trenches 116. For example, the depth of the placeholder cavity trenches 116 in the semiconductor layer 101 can be in a range of approximately 20 nm to 70 nm, and the width of the placeholder cavity trenches 116 can be in a range of approximately 10 nm to 50 nm.

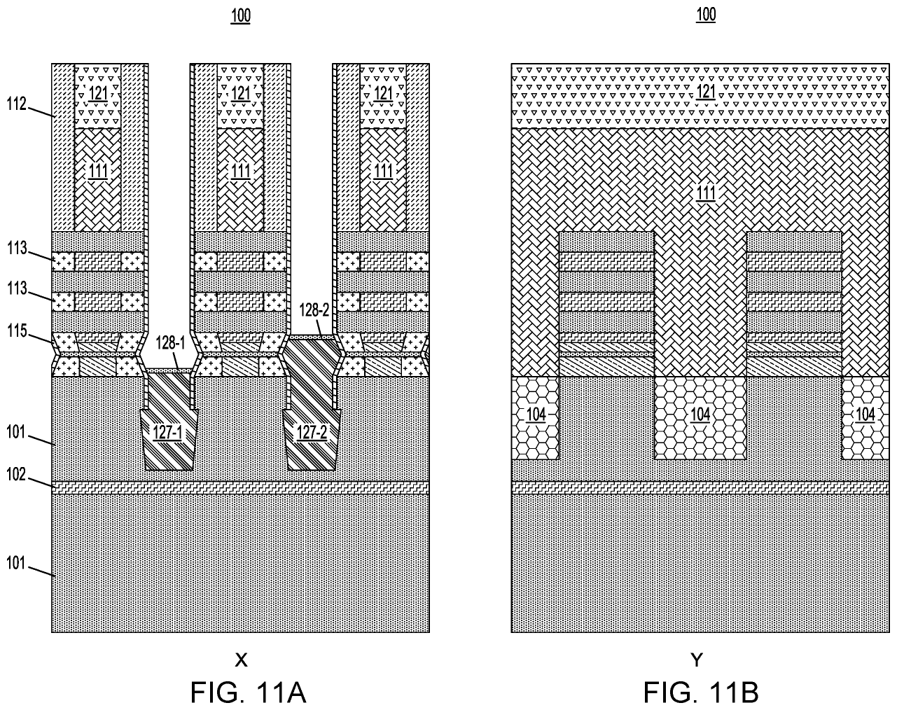

FIGS. 11A and 11B show cross-sectional views, which respectively correspond to the lines X and Y in FIG. 1, of the semiconductor structure 100 following formation of sacrificial placeholders 127-1 and 127-2 (collectively “sacrificial placeholders 127”) and placeholder caps 128-1 and 128-2 (collectively “placeholder caps 128”), according to an illustrative embodiment. For example, the placeholder cavity trenches 116 can be filled with sacrificial materials to form the sacrificial placeholders 127-1 and 127-2. In illustrative embodiments, the sacrificial placeholders 127 can comprise, for example, SiGe, III-V semiconductor material or other semiconductor material. The placeholder caps 128 can comprise, for example, silicone or some other suitable capping layer material. The sacrificial placeholders 127 can be epitaxially grown from the exposed portions of the semiconductor layer 101, and the placeholder caps 128 can be epitaxially grown from the exposed surfaces of their corresponding sacrificial placeholders 127, for example.

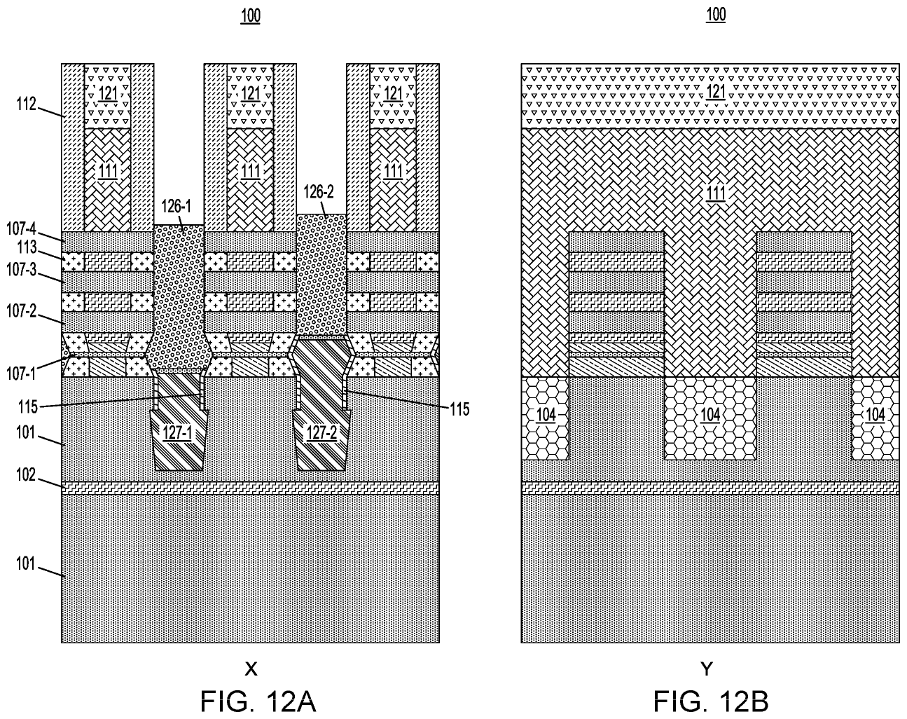

FIGS. 12A and 12B show cross-sectional views, which respectively correspond to the lines X and Y in FIG. 1, of the semiconductor structure 100 following removal of portions of the protective liner 115 and growth of epitaxial layers for source/drain regions, according to an illustrative embodiment. Exposed portions of the protective liner 115 are removed and source/drain regions 126-1 and 126-2 (collectively “source/drain regions 126”) are formed. The exposed portions of the protective liner 115 may be removed using any suitable etch process, such as atomic layer etching (ALE), isotropic etching, etc. The source/drain regions 126 can be epitaxially grown from the exposed surfaces of their corresponding placeholder caps 128.

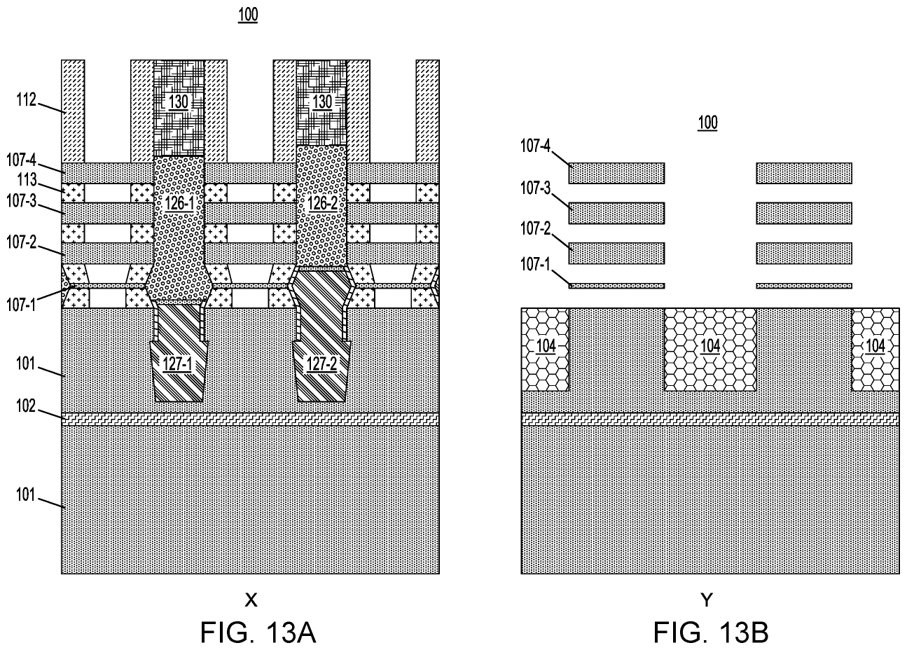

FIGS. 13A and 13B show cross-sectional views, which respectively correspond to the lines X and Y in FIG. 1, of the semiconductor structure 100 following formation of an ILD layer 130, a POC process, removal of the dummy gate portions 111, and removal of the additional sacrificial layers 103, and the sacrificial layers 105, according to an illustrative embodiment. The ILD layer 130 is deposited to fill in portions on and around the source/drain regions 126. The ILD layer 130 is deposited using deposition techniques such as, for example, CVD, PECVD, RFCVD, PVD, ALD, MBD, PLD, and/or LSMCD, followed by a planarization process, such as, a POC process, to remove excess portions of the ILD layer 130 deposited on top of the HM layer 121 and gate spacers 112, and to remove the HM layer 121 and portions of the gate spacers 112 to expose the dummy gate portions 111. The ILD layer 130 may comprise, for example, SiOx, SiOC, SiOCN or some other dielectric.

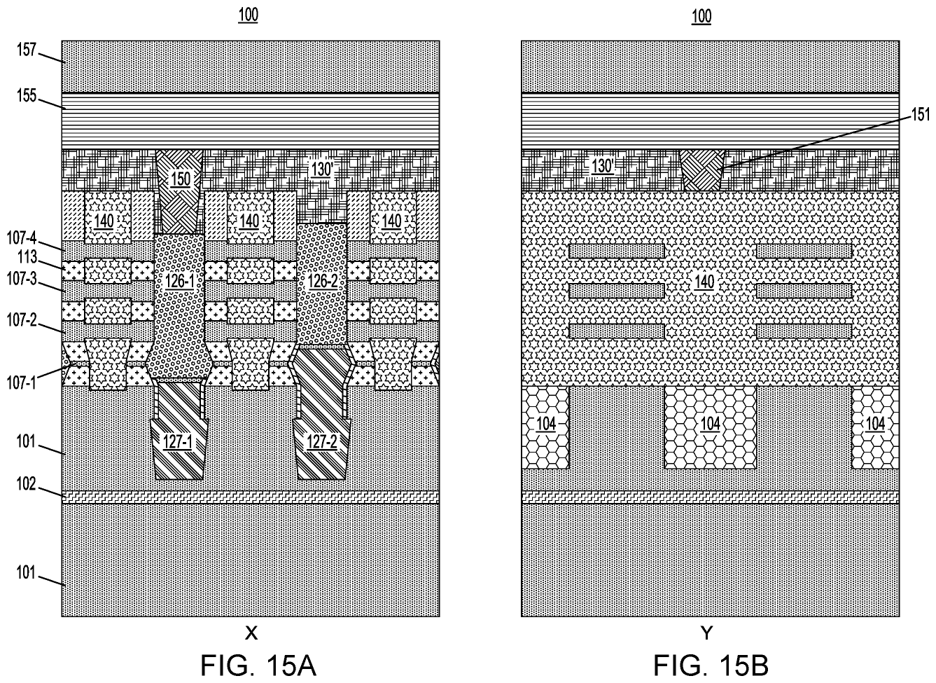

The dummy gate portions 111, the additional sacrificial layers 103, and the sacrificial layers 105 are selectively removed to create vacant areas, in which gate regions 140 (which may also be referred to as gate structures) will be formed, as described in more detail in conjunction with FIGS. 15A and 15B. For example, the dummy gate portions 111 can be selectively removed using hot ammonia to remove a-Si, and the additional sacrificial layers 103 and the sacrificial layers 105 can be selectively removed with respect to the channel layers 107 using, for example, a dry HCl etch.

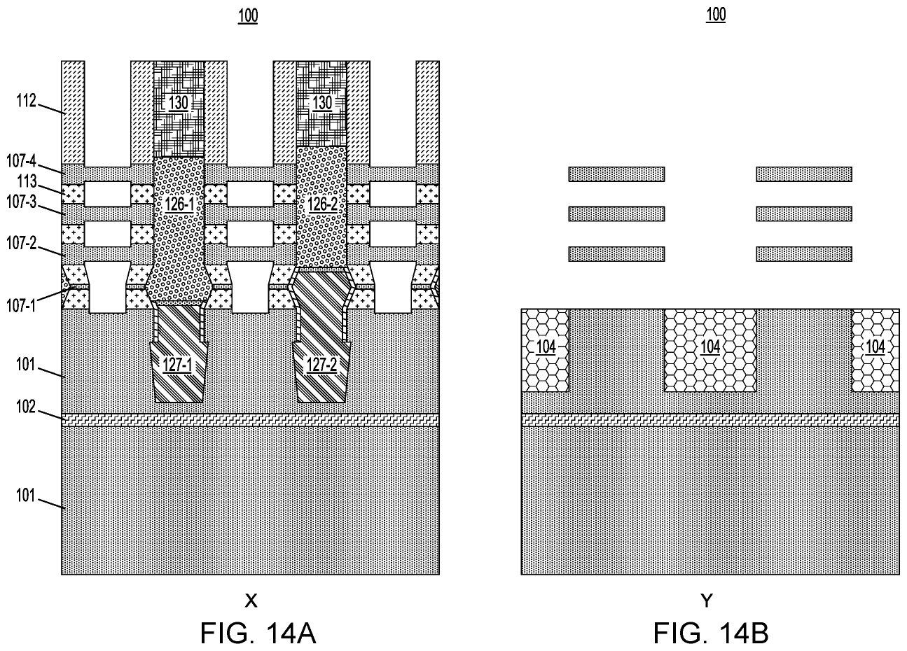

FIGS. 14A and 14B show cross-sectional views, which respectively correspond to the lines X and Y in FIG. 1, of the semiconductor structure 100 following a nanosheet trimming process, according to an illustrative embodiment. A trimming method is performed to completely remove portions of the channel layer 107-1. In this embodiment, the channel layer 107-1 along the cross-sectional view shown in FIG. 14B is completely removed. The exposed portions of the channel layer 107-1 above the exposed portions of the semiconductor layer 101 that are adjacent to the source/drain region 126-1 are also removed in this example. The channel layers 107 can be trimmed selectively by etching, such as by using a wet or dry etch process using. In this particular embodiment, it is noted that some portions of the channel layer 107-1 remain intact, such as the portions shown to the left and right of the sacrificial placeholder 127-1 and the sacrificial placeholder 127-2.

FIGS. 15A and 15B show cross-sectional views of the semiconductor structure 100, respectively corresponding to lines X and Y in FIG. 1, following formation of the gate regions 140, MOL contacts, frontside BEOL interconnects 155, and carrier wafer bonding, according to an illustrative embodiment. The gate regions 140, including, for example, gate and dielectric portions are formed (e.g., using a replacement metal gate process) in the vacant portions left by the removal of the dummy gate portions 111, the additional sacrificial layers 103, the sacrificial layers 105, and the trimming of the channel layers 107. In illustrative embodiments, each of the gate regions 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate regions 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Formation of the MOL contacts, the frontside BEOL interconnects 155 and the carrier wafer bonding can include depositing additional ILD material on top of the ILD layer 130, the gate spacers 112, and the gate regions 140 to form an ILD layer 130′, and forming a frontside source/drain contact 150, a gate contact 151, frontside BEOL interconnects 155, and bonding of the structure (e.g., the frontside BEOL interconnects 155) to a carrier wafer 157. The frontside source/drain contact 150 is formed in the ILD layer 130′ to contact the top surface of source/drain region 126-1. In forming the frontside source/drain contact 150, an opening is formed through a portion of the ILD layer 130′. The opening exposes at least a portion of the source/drain region 126-1 on which the frontside source/drain contact 150 is formed. According to an embodiment, masks can be formed on parts of the ILD layer 130′, and an exposed portion of the ILD layer 130′ corresponding to where the opening is to be formed is removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the opening to form the frontside source/drain contact 150. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the ILD layer 130′. The frontside source/drain contact 150 extends through the ILD layer 130′ to land on and contact the source/drain region 126-1.

In some embodiments, the gate contact 151 is formed through the ILD layer 130′ to land on and contact a corresponding gate region 140. The process and materials used for forming the gate contacts are similar to those used for forming the frontside source/drain contact 150.

The frontside BEOL interconnects 155 include various BEOL interconnect structures. The carrier wafer 157 may be formed of materials similar to that of the semiconductor layer 101, and may be formed over the frontside BEOL interconnects 155 using a wafer bonding process, such as dielectric-to-dielectric bonding.

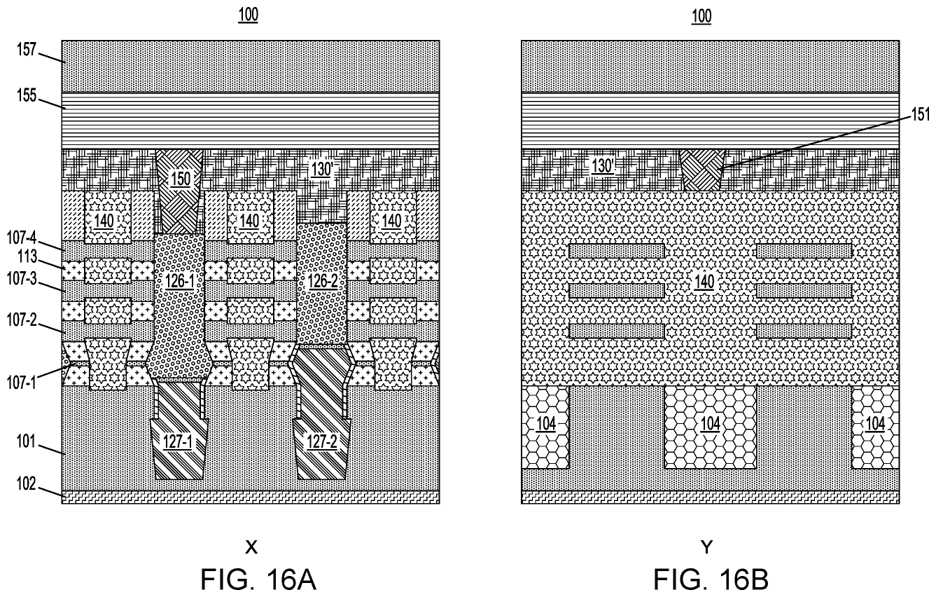

FIGS. 16A-16B show cross-sectional views of the semiconductor structure 100, respectively corresponding to lines X and Y in FIG. 1, following wafer flipping and removal of the semiconductor layer 101 to the etch stop layer 102, according to an illustrative embodiment. For example, using the carrier wafer 157, the semiconductor structure 100 may be “flipped” (for example, rotated 180 degrees) so that the structure is inverted. In addition, the semiconductor layer 101 is removed from the backside of the semiconductor structure 100 stopping at the etch stop layer 102. The removal process can include, for example, etching the semiconductor layer with an etchant that selectively etches silicon with respect to a material of the etch stop layer 102.

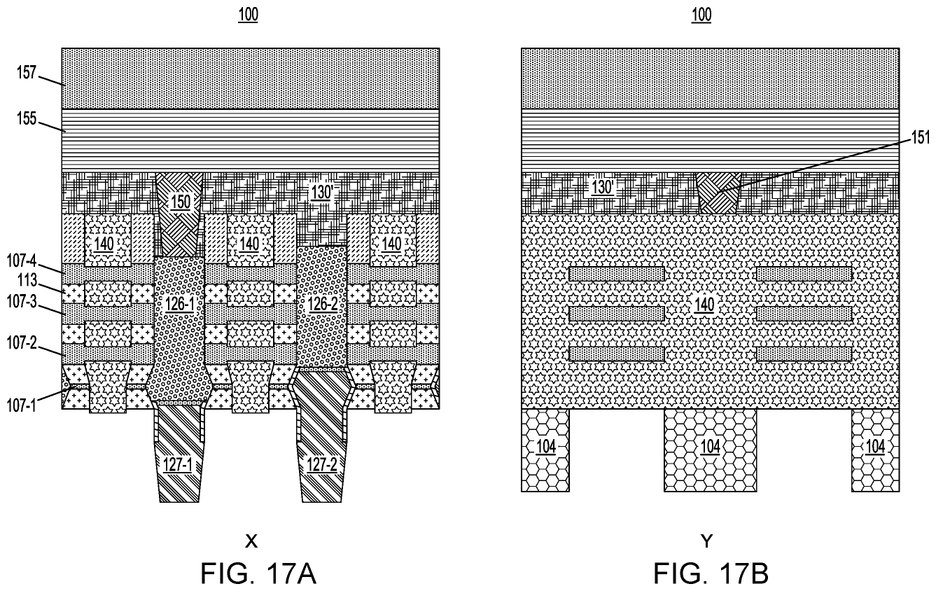

FIGS. 17A-17CB show cross-sectional views of the semiconductor structure 100, respectively corresponding to lines X and Y in FIG. 1, following removal of the etch stop layer 102 and the remaining semiconductor layer 101, according to an illustrative embodiment. The etching process for removal of the etch stop layer 102 can include, for example, IBE by Ar/CHF3 based chemistry. Etchants for removing the semiconductor layer 101 include, for example, KOH and TMAH.

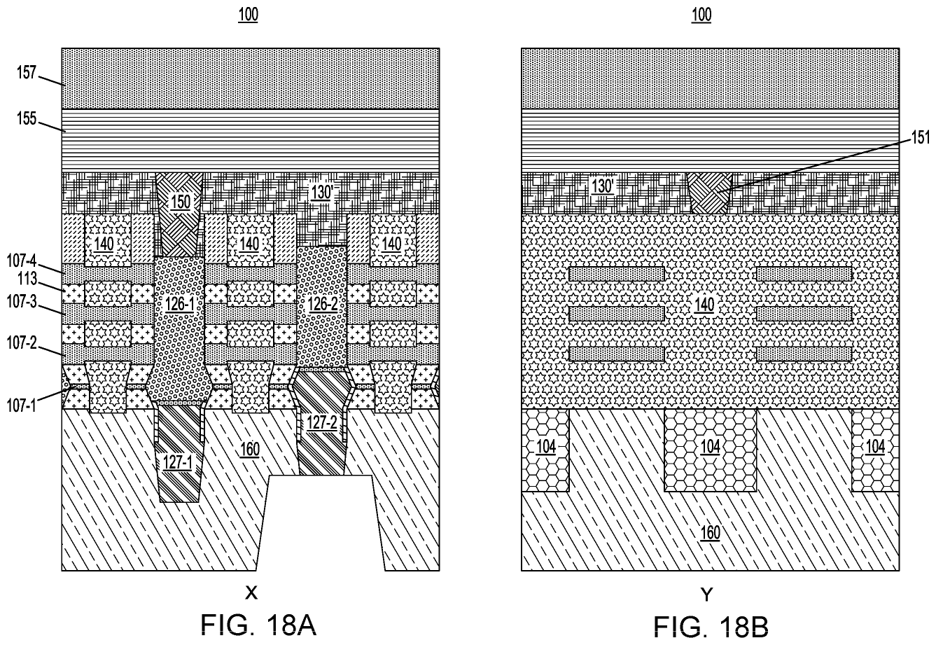

FIGS. 18A-18C show cross-sectional views, respectively corresponding to lines X and Y, of the semiconductor structure 100 following formation of a backside ILD layer 160 and backside ILD layer patterning, according to an illustrative embodiment. The backside ILD layer 160 can be deposited using deposition techniques such as, for example, CVD, PECVD, RFCVD, PVD, ALD, MBD, PLD, and/or LSMCD, followed by a planarization process, such as, CMP to form the backside ILD layer 160. The backside ILD layer 160 may comprise, for example, SiOₓ, SiOC, SiOCN or some other dielectric.

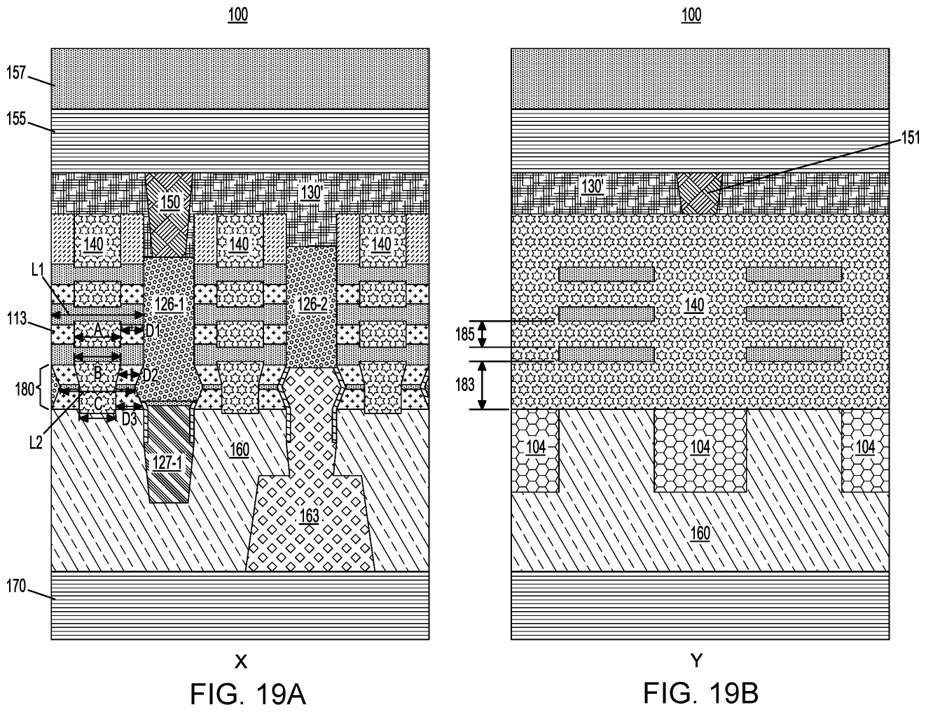

The backside ILD layer patterning can include depositing a mask with openings where a backside source/drain contact 163 is to be formed (as shown in FIG. 19A), and then selectively removing the exposed portions of the backside ILD layer 160 using, for example, a dry etching process using a RIE or IBE process, a wet chemical etching process or a combination of these etching processes. A dry etch may be performed using a plasma. Such wet or dry etch processes include, for example, IBE by Ar/CHF3 based chemistry. For example, in FIG. 18A, an exposed portion of the backside ILD layer 160 is removed to expose the bottom portion of the sacrificial placeholder 127-2.

FIGS. 19A-19B show cross-sectional views, respectively corresponding to lines X and Y, of the semiconductor structure 100 following removal of the sacrificial placeholder 127-2, formation of the backside source/drain contact 163, and formation of backside BEOL layers 170, according to an illustrative embodiment. The sacrificial placeholder 127-2 (and the corresponding placeholder cap 128-2) can be selectively removed to expose backside portions of the bottom source/drain region 126-2. The sacrificial placeholder 127-2 and the corresponding placeholder cap 128-2 can be removed using, for example, a selective dry or wet etch process.

A backside source/drain contact 163 may be formed by fill and planarization of contact material. The contact material of the backside source/drain contact 163 may be similar to that of the frontside source/drain contact 150, for example. The backside source/drain contact 163 contacts a backside of the source/drain region 126-2.

The backside BEOL layers 170 (also referred to herein as backside interconnects) are formed on the backside ILD layer 160 and on the backside source/drain contact 163. The backside BEOL layers 170 can include various backside power delivery network structures such as, but not necessarily limited to, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits. The backside source/drain contact 163 is connected to the backside BEOL layers 170. In some embodiments, the backside BEOL layers 170 can alternatively or additionally be used for routing of signals, including power and/or clock signals as non-limiting examples.

As shown in FIG. 19A, the resulting semiconductor structure 100 includes the backside source/drain contact 163 that contacts the source/drain region 126-2. The source/drain region 126-1 is enlarged relative to the source/drain region 126-2. The portion 180 of the source/drain region 126-1 below the channel layer 107-2 is disposed between curved-shaped structures. The curved-shaped structures are formed by portions of the channel layer 107-1 that are disposed between two layers of the dielectric material corresponding to the inner spacers 114.

In some embodiments, the lengths (e.g., length B shown in FIG. 19A) of the top portion of the gate regions 140 corresponding to portion 180 are greater than the lengths (e.g., length C shown in FIG. 19A) of the bottom portions of the gate regions 140 corresponding to portion 180. Additionally, or alternatively, length B can be equal to the length of the gates between one or more other channel layers (e.g., length A, which corresponds to the length of the gate regions 140 between the channel layer 107-2 and 107-3).

In at least one embodiment, a height of a bottom suspension region 183 between the channel layer 107-2 and the backside ILD layer 160 is greater than a height of at least one other suspension region, such as suspension region 185 between the channel layer 107-2 and the channel layer 107-3.

The length of the channel layer 107-2 corresponding to L1 can be greater than a length of the channel layer 107-1 corresponding to L2. The difference between L1 and L2 results from the tip loss of the channel layer 107-1 during the indentation process described in conjunction with FIGS. 6A and 6B and also results in the enlarged size of the source/drain region 126-1.

In some embodiments, the length, D1, of the inner spacers 114 between the channel layer 107-2 and the channel layer 107-3 is equal to the length, D2, of the inner spacers 114 between the channel layer 107-1 and the channel layer 107-2. This indicates that the length of such inner spacers 114 is not impacted by the tip loss of the channel layer 107-1. Additionally, in at least one embodiment, the length, D3, of the inner spacers 114 between the backside ILD layer 160 and the channel layer 107-1 is greater than D1. This can advantageously reduce parasitic gate to source/drain parasitic capacitance.

At least some embodiments described herein can form a stacked transistor structure having a direct backside contact without needing to form a bottom dielectric (BDI) layer. Without in any way limiting the scope, interpretation, or application of the claims appearing below, a technical effect of one or more of the example embodiments disclosed herein is avoiding the need to apply a thick inner spacer liner to pinch-off a thick bottom suspension region due to how the indentations are formed using the thin channel layer. Another technical effect of one or more of the example embodiments disclosed herein is allowing a broader range of placeholder heights due to the thicker bottom suspension regions. Yet another technical effect of one or more of the example embodiments disclosed herein is reducing insulator thickness because of, for example, the spacing of the inner spacers and the bottom suspension regions. Some embodiments initially have an enlarged placeholder size, which can compensate for SiGe loss during silicone removal, for example.

According to an aspect of the invention, a semiconductor device comprises a first stacked transistor structure and a second stacked transistor structure disposed above an interlayer dielectric layer, each comprising a plurality of channel layers alternately stacked with a plurality of gate regions, and a first source/drain region that contacts the plurality of channel layers of the first stacked transistor structure and the second stacked transistor structure. At least a portion of the first source/drain region that is above the interlayer dielectric layer and below a first channel layer of the plurality of channel layers is disposed between curved-shaped inner spacer structures of the first stacked transistor structure and the second stacked transistor structure. A first source/drain contact is connected to the first source/drain region.

The semiconductor device of the illustrative embodiment advantageously includes the curved-shaped inner spacer structures to provide a thicker bottom suspension region, which can help accommodate different heights of placeholders (e.g., resulting from variations in the fabrication process) used to form source/drain contacts.

In embodiments, a first gate region of the plurality of gate regions is disposed above the interlayer dielectric layer and below the first channel layer. A first surface of the first gate region that contacts the interlayer dielectric layer is a first length, and a second surface of the first gate region that contacts the first channel layer is a second length that is different than the first length.

In embodiments, a second gate region of the plurality of gate regions is disposed between at least two consecutive channel layers, and the second gate region is a same length as the second length. The at least two consecutive channel layers may correspond to channel layer 107-2 and channel layer 107-3, as a non-limiting example.

In embodiments, the interlayer dielectric layer and the first channel layer of the plurality of channel layers are spaced apart from each other at a first distance and at least two consecutive channel layers of the plurality of channel layers are spaced apart from each other at a second distance that is different than the first distance.

In embodiments, each of the curved-shaped inner spacer structures includes a first inner spacer disposed above the interlayer dielectric layer, a second inner spacer disposed below the first channel layer, and a silicone layer disposed between the first and second inner spacers.

In embodiments, the silicone layer disposed between the first and second inner spacers is thinner than each of the plurality of channel layers.

In embodiments, the first stacked transistor structure comprises at least two curved-shaped inner spacer structures and the silicone layer, and a length spanning the silicone layers of the at least two curved-shaped inner spacer structures and one of the plurality of gate regions that is disposed above the interlayer dielectric layer and below the first channel layer is less than a length of the first channel layer.

In embodiments, a length of the first inner spacer is greater than a length of the second inner spacer.

In embodiments, a length of the second inner spacer is a same length as an inner spacer that is disposed between two consecutive channel layers of the plurality of channel layers.

In embodiments, the semiconductor structure includes a second source/drain region that contacts the plurality of channel layers of the second stacked transistor structure, and a second source/drain contact disposed beneath the second source/drain region. A portion of the second source/drain contact extends above the interlayer dielectric layer and below the first channel layer.

According to an aspect of the invention, a semiconductor device comprises a first source/drain region that contacts channel layers of a first stacked transistor structure and a second stacked transistor structure, and a second source/drain region that contacts channel layers of the second stacked transistor structure and a third stacked transistor structure. A backside source/drain contact is connected to the second source/drain region, where a bottom portion of the first source/drain region is disposed between a first curved-shaped inner spacer structure of the first stacked transistor structure and a second curved-shaped inner spacer structure of the second stacked transistor structure. The backside source/drain contact is disposed between a third curved-shaped inner spacer structure of the second stacked transistor structure and a fourth curved-shaped inner spacer structure of the third stacked transistor structure.

The semiconductor device of the illustrative embodiment advantageously includes the curved-shaped inner spacer structures to provide a thicker bottom suspension region, which can help accommodate different heights of placeholders (e.g., resulting from variations in the semiconductor fabrication process) used to form source/drain contacts.

In embodiments, each of the curved-shaped inner spacer structures includes a first inner spacer disposed above an interlayer dielectric layer, a second inner spacer disposed below a first one of the channel layers, and a silicone layer disposed between the first and second inner spacers.

In embodiments, the silicone layer of the first curved-shaped inner spacer structure is thinner than the channel layers corresponding to the first stacked transistor structure.

In embodiments, a length spanning the silicone layers of the second and third curved-shaped inner spacer structures and a gate region disposed therebetween is less than a length of the channel layers of the second stacked transistor structure.

In embodiments, a length of the first inner spacer of the first curved-shaped inner spacer structure is greater than a length of the second inner spacer of the first curved-shaped inner spacer structure.

In embodiments, the length of the second inner spacer of the first curved-shaped inner spacer structure is a same length as an inner spacer that is disposed between two consecutive channel layers of the first stacked transistor structure.

In embodiments, the channel layers of the second stacked transistor structure are disposed above an interlayer dielectric layer and alternately stacked with a plurality of gate regions, and a first gate region of the plurality of gate regions is disposed above the interlayer dielectric layer and between the second and third curved-shaped inner spacer structures of the second stacked transistor structure. A first surface of the first gate region that contacts the interlayer dielectric layer is a first length, and a second surface of the first gate region that contacts a bottommost one of the channel layers of the second stacked transistor structure is a second length that is different than the first length.

According to yet another aspect of the invention, a method includes forming a set of channel layers alternately stacked with a set of sacrificial layers on a semiconductor layer, wherein a first channel layer in the set of channel layers is thinner than the other channel layers in the set of channel layers, and forming indentations in the sacrificial layers in the set of sacrificial layers, wherein the indentations formed for the sacrificial layers adjacent to the first channel layer are deeper than the other sacrificial layers in the set of sacrificial layers. The method also includes forming inner spacers between each of the channel layers in the set of channel layers and forming a source/drain region and curved-shaped inner spacer structures, where the source/drain region is disposed between the curved-shaped inner spacer structures, and where at least a portion of the source/drain region is formed below the first channel layer in the set of channel layers. Forming the curved-shaped inner spacer structures includes removing the set of sacrificial layers and trimming at least the first channel layer.

The method of the illustrative embodiment advantageously forms the curved-shaped inner spacer structures to provide a thicker bottom suspension region, which can help accommodate different heights of placeholders (e.g., resulting from variations in the semiconductor fabrication process) used to form source/drain contacts.

In one or more additional illustrative embodiments, the sacrificial layers adjacent to the first channel layer are a different type of sacrificial material than the other sacrificial layers in the set of sacrificial layers.

In one or more additional illustrative embodiments, the method includes forming one or more gate regions, where a first gate region of the one or more gate regions is disposed above an interlayer dielectric layer and below the first channel layer. A first surface of the first gate region that contacts the interlayer dielectric layer is a first length, and a second surface of the first gate region that contacts the first channel layer is a second length that is different than the first length.

Semiconductor devices and methods for forming the same in accordance with the above-described techniques can be employed in various applications, hardware, and/or electronic systems. Suitable hardware and systems for implementing embodiments of the present disclosure may include, but are not limited to, personal computers, communication networks, electronic commerce systems, portable communications devices (for example, cell and smart phones), solid-state media storage devices, functional circuitry, etc. Systems and hardware incorporating the semiconductor devices are contemplated embodiments of the present disclosure. Given the teachings provided herein, one of ordinary skill in the art will be able to contemplate other implementations and applications of embodiments of the present disclosure.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard; or (b) an end product. The end product can be any product that includes integrated circuit chips, ranging from toys and other low-end applications to advanced computer products having a display, a keyboard or other input device, and a central processor.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments described herein have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first stacked transistor structure and a second stacked transistor structure disposed above an interlayer dielectric layer, each comprising a plurality of channel layers alternately stacked with a plurality of gate regions;
a first source/drain region that contacts the plurality of channel layers of the first stacked transistor structure and the second stacked transistor structure, wherein at least a portion of the first source/drain region that is above the interlayer dielectric layer and below a first channel layer of the plurality of channel layers is disposed between curved-shaped inner spacer structures of the first stacked transistor structure and the second stacked transistor structure; and
a first source/drain contact connected to the first source/drain region.

2. The semiconductor device of claim 1, wherein a first gate region of the plurality of gate regions is disposed above the interlayer dielectric layer and below the first channel layer, and wherein a first surface of the first gate region that contacts the interlayer dielectric layer is a first length, and a second surface of the first gate region that contacts the first channel layer is a second length that is different than the first length.

3. The semiconductor device of claim 2, wherein a second gate region of the plurality of gate regions is disposed between at least two consecutive channel layers, and wherein the second gate region is a same length as the second length.

4. The semiconductor device of claim 1, wherein the interlayer dielectric layer and the first channel layer of the plurality of channel layers are spaced apart from each other at a first distance and at least two consecutive channel layers of the plurality of channel layers are spaced apart from each other at a second distance that is different than the first distance.

5. The semiconductor device of claim 1, wherein each of the curved-shaped inner spacer structures comprises:
a first inner spacer disposed above the interlayer dielectric layer;
a second inner spacer disposed below the first channel layer; and
a silicone layer disposed between the first and second inner spacers.

6. The semiconductor device of claim 5, wherein the silicone layer disposed between the first and second inner spacers is thinner than each of the plurality of channel layers.

7. The semiconductor device of claim 5, wherein the first stacked transistor structure comprises at least two curved-shaped inner spacer structures and the silicone layer, and wherein a length spanning the silicone layers of the at least two curved-shaped inner spacer structures and one of the plurality of gate regions that is disposed above the interlayer dielectric layer and below the first channel layer is less than a length of the first channel layer.

8. The semiconductor device of claim 5, wherein a length of the first inner spacer is greater than a length of the second inner spacer.

9. The semiconductor device of claim 5, wherein a length of the second inner spacer is a same length as an inner spacer that is disposed between two consecutive channel layers of the plurality of channel layers.

10. The semiconductor device of claim 1, comprising:
a second source/drain region that contacts the plurality of channel layers of the second stacked transistor structure; and
a second source/drain contact disposed beneath the second source/drain region, wherein a portion of the second source/drain contact extends above the interlayer dielectric layer and below the first channel layer.

11. A semiconductor device comprising:
a first source/drain region that contacts channel layers of a first stacked transistor structure and a second stacked transistor structure;
a second source/drain region that contacts channel layers of the second stacked transistor structure and a third stacked transistor structure; and
a backside source/drain contact connected to the second source/drain region;
wherein a bottom portion of the first source/drain region is disposed between a first curved-shaped inner spacer structure of the first stacked transistor structure and a second curved-shaped inner spacer structure of the second stacked transistor structure, and wherein the backside source/drain contact is disposed between a third curved-shaped inner spacer structure of the second stacked transistor structure and a fourth curved-shaped inner spacer structure of the third stacked transistor structure.

12. The semiconductor device of claim 11, wherein each of the curved-shaped inner spacer structures comprises:
a first inner spacer disposed above an interlayer dielectric layer;
a second inner spacer disposed below a first one of the channel layers; and
a silicone layer disposed between the first and second inner spacers.

13. The semiconductor device of claim 12, wherein the silicone layer of the first curved-shaped inner spacer structure is thinner than the channel layers corresponding to the first stacked transistor structure.

14. The semiconductor device of claim 12, wherein a length spanning the silicone layers of the second and third curved-shaped inner spacer structures and a gate region disposed therebetween is less than a length of the channel layers of the second stacked transistor structure.

15. The semiconductor device of claim 12, wherein:
a length of the first inner spacer of the first curved-shaped inner spacer structure is greater than a length of the second inner spacer of the first curved-shaped inner spacer structure.

16. The semiconductor device of claim 12, wherein a length of the second inner spacer of the first curved-shaped inner spacer structure is a same length as an inner spacer that is disposed between two consecutive ones of the channel layers of the first stacked transistor structure.

17. The semiconductor device of claim 11, wherein:
the channel layers of the second stacked transistor structure are disposed above an interlayer dielectric layer and alternately stacked with a plurality of gate regions;
a first gate region of the plurality of gate regions is disposed above the interlayer dielectric layer and between the second and third curved-shaped inner spacer structures of the second stacked transistor structure; and
a first surface of the first gate region that contacts the interlayer dielectric layer is a first length, and a second surface of the first gate region that contacts a bottommost one of the channel layers of the second stacked transistor structure is a second length that is different than the first length.

18. A method comprising:
forming a set of channel layers alternately stacked with a set of sacrificial layers on a semiconductor layer, wherein a first channel layer in the set of channel layers is thinner than the other channel layers in the set of channel layers;
forming indentations in the sacrificial layers in the set of sacrificial layers, wherein the indentations formed for the sacrificial layers adjacent to the first channel layer are deeper than the other sacrificial layers in the set of sacrificial layers;
forming inner spacers between each of the channel layers in the set of channel layers; and
forming a source/drain region and curved-shaped inner spacer structures, wherein the source/drain region is disposed between the curved-shaped inner spacer structures, and wherein at least a portion of the source/drain region is formed below the first channel layer in the set of channel layers, wherein forming the curved-shaped inner spacer structures comprises removing the set of sacrificial layers and trimming at least the first channel layer.

19. The method of claim 18, wherein the sacrificial layers adjacent to the first channel layer comprise a different type of sacrificial material than the other sacrificial layers in the set of sacrificial layers.

20. The method of claim 18, comprising:
forming one or more gate regions, wherein a first gate region of the one or more gate regions is disposed above an interlayer dielectric layer and below the first channel layer, and wherein a first surface of the first gate region that contacts the interlayer dielectric layer is a first length, and a second surface of the first gate region that contacts the first channel layer is a second length that is different than the first length.
